(19) United States
(12) Patent Application Publication
(10) Pub. No.: US 2009/0288701 A1
(43) Pub. Date: Nov. 26, 2009

(54) SOLAR CELL LAMINATES HAVING COLORED MULTI-LAYER ENCAPSULANT SHEETS

(75) Inventors: RICHARD ALLEN HAYES, Beaumont, TX (US); REBECCA L. SMITH, Vienna, WV (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E.I.DU PONT DE NEMOURS AND COMPANY, Wilmington, DE (US)

(21) Appl. No.: 12/430,275

(22) Filed: Apr. 27, 2009

Related U.S. Application Data
(60) Provisional application No. 61/128,737, filed on May 23, 2008.

(51) Int. Cl. H01L 31/048; H01L 31/0256; H01L 31/18

(52) U.S. Cl. 136/251; 136/258; 438/65; 257/E31.003

(57) ABSTRACT

Solar cell modules are provided having a solar cell layer and a colored multi-layer encapsulant sheet where an uncolored surface sub-layer of the encapsulant sheet is in direct contact with the solar cell layer.

### CROSS-REFERENCE TO RELATED APPLICATIONS

This application claims priority from U.S. Patent Application Ser. No. 61/128,737, filed on May 23, 2008, which is incorporated herein by reference.

### FIELD OF THE INVENTION

The invention relates to solar cell modules comprising colored multi-layer encapsulant sheets.

### BACKGROUND OF THE INVENTION

Because they provide a sustainable energy resource, the use of solar cells is rapidly expanding. Solar cells can typically be classified into two categories based on the light absorbing material used, i.e., bulk or wafer-based solar cells and thin film solar cells.

Monocrystalline silicon (c-Si), poly- or multi-crystalline silicon (poly-Si or mc-Si) and ribbon silicon are the materials used most commonly in forming the more traditional wafer-based solar cells. Solar cell modules derived from wafer-based solar cells often comprise a series of about 180 and about 240 μm thick self-supporting wafers (or cells) that are soldered together. Such a panel of solar cells is called a solar cell layer and it may further comprise electrical wirings such as cross ribbons connecting the individual cell units and bus bars having one end connected to the cells and the other exiting the module. The solar cell layer is then further laminated to encapsulant layer(s) and protective layer(s) to form a weather resistant module that may be used for up to 25 to 30 years. In general, a solar cell module derived from wafer-based solar cell(s) comprises, in order of position from the front light-receiving side to the back non-light-receiving side: (1) an incident layer, (2) a front encapsulant layer, (3) a solar cell layer, (4) a back encapsulant layer, and (5) a backing layer.

Solar cells of the increasingly important alternative type, i.e. thin film solar cells, are commonly formed from materials that include amorphous silicon (a-Si), microcrystalline silicon (μc-Si), cadmium telluride (CdTe), copper indium selenide (CuInSe2 or CIS), copper indium/gallium diselenide (CuInxGa(1-x)Se2 or CIGS), light absorbing dyes and organic semiconductors. By way of example, thin film solar cells are disclosed in e.g., U.S. Pat. Nos. 5,507,881; 5,512,107; 5,948,176; 5,994,163; 6,040,521; 6,137,048; and 6,258,620 and U.S. Patent Publication Nos. 20070298590; 20070281090; 20070240759; 20070232057; 20070238285; 20070227578; 20070209699; and 20070079866. Thin film solar cells with a typical thickness of less than 2 μm are produced by depositing semiconductor layers onto a superstrate or substrate formed of glass or a flexible film. During manufacture, it is common to include a laser scribing sequence that enables adjacent cells to be directly interconnected in series, with no need for further solder connections between cells. As with wafer cells, the solar cell layer may further comprise electrical wirings such as cross ribbons and bus bars. Similarly, the thin film solar cells are further laminated to other encapsulant and protective layers to produce a weather resistant and environmentally robust module. Depending on the sequence in which the multi-layer deposition is carried out, the thin film solar cells may be deposited on a superstrate that ultimately serves as the incident layer in the final module, or the cells may be deposited on a substrate that is utilized as the backing layer in the final module. Therefore, a solar cell module derived from thin film solar cells may have one of two types of construction. The first type includes, in order of position from the front light-receiving side to the back non-light-receiving side, (1) a solar cell layer comprising a superstrate and a layer of thin film solar cell(s) deposited thereon at the non-light-receiving side, (2) a (back) encapsulant layer, and (3) a backing layer. The other type may include, in order of position from the front light-receiving side to the back non-light-receiving side, (1) an incident layer, (2) a (front) encapsulant layer, and (3) a solar cell layer comprising a layer of thin film solar cell(s) deposited on a substrate at the light-receiving side thereof.

The encapsulant layers used in solar cell modules are designed to encapsulate and protect the fragile solar cells. Suitable polymeric materials used in the solar cell encapsulant layers typically possess a combination of characteristics such as high transparency, low haze, high impact resistance, high penetration resistance, good ultraviolet (UV) light resistance, good long term thermal stability, adequate adhesion strength to glass and other rigid polymeric sheets, high moisture resistance, and good long term weatherability. In addition, the optical properties of the front encapsulant layer may be such that light can be effectively transmitted to the solar cell layer.

In recent years, solar cell modules have been incorporated into an increasing number of architectural structures. In order to improve the design characteristics and ensure harmony with the surroundings, colored solar cell encapsulants are also being developed, see e.g., U.S. Pat. No. 6,660,930 and Japanese Patent Nos. JP 2001-047568; JP 2001-053298; JP 2003-258283; and JP 2005-050927. Because the colored solar encapsulants often contain color pigments (e.g., carbon black) that are electrically conductive, the volume resistivity of the colored encapsulants is reduced compared to that of encapsulants that are free of such electrically conductive color pigments. In addition, because the colored encapsulants are in direct contact with the solar cells, the reduction of volume resistivity may cause voltage loss, which in turn, would reduce power output from the solar cells. Even small reductions in the volume resistivity of the colored encapsulants can cause significant power loss when calculated over the typical lifetime (generally 20-30 years) of the solar cell modules.

### SUMMARY OF THE INVENTION

The present invention is directed to a solar cell module comprising a laminate structure, the laminate structure comprising a solar cell layer and a colored multi-layer polymeric sheet, wherein
(A) the solar cell layer is selected from the group consisting of solar cell layers comprising a single solar cell and solar cell layers comprising a plurality of electrically interconnected solar cells;
(B) the solar cell layer has a light-receiving side and a non-light-receiving side; and
(C) the colored multi-layer polymeric sheet comprises 1) a first surface sub-layer that is positioned such that it is adjacent to and in direct contact with the solar cell layer, 2) a second surface sub-layer positioned such that it does not contact the solar cell layer, and 3) optionally at least one inner sub-layer positioned between the two surface sub-layers, wherein
   (i) the first surface sub-layer is uncolored and substantially free of electrically conductive color pigment; and
   (ii) at least one sub-layer, other than the first surface sub-layer, is colored and comprises at least one electrically conductive color pigment.

The invention is further directed to a process for preparing a solar cell module, comprising: (i) providing an assembly comprising all the component layers of the solar cell module described above, and (ii) laminating the assembly to form the solar cell module.

The invention is yet further directed to a process for preparing a solar cell module, comprising:

(A) providing an assembly comprising, in order of position,
(1) a solar cell layer,
(2) a first polymeric sheet that is uncolored and substantially free of any electrically conductive color pigment, and
(3) a second polymeric sheet that is colored and comprising at least one electrically conductive color pigment,

wherein
(i) the solar cell layer is selected from the group consisting of solar cell layers comprising a single solar cell and solar cell layers comprising a plurality of electrically interconnected solar cells;
(ii) the solar cell layer has a light-receiving side and a non-light-receiving side; and
(iii) the uncolored first polymeric sheet is in direct contact with the non-light-receiving side of the solar cell layer, and

(B) laminating the assembly to form the solar cell module.

### BRIEF DESCRIPTION OF THE DRAWINGS

FIG. 1 is a cross-sectional view, not-to-scale, of a colored multi-layer polymeric sheet in the form of a bi-layer sheet.

FIG. 2 is a cross-sectional view, not-to-scale, of a colored multi-layer polymeric sheet in the form of a tri-layer sheet.

FIG. 3 is a cross-sectional view, not-to-scale, of a wafer-based solar cell module disclosed herein.

FIG. 4 is a cross-sectional view, not-to-scale, of a thin film solar cell module disclosed herein.

### DETAILED DESCRIPTION OF THE INVENTION

Unless otherwise defined, all technical and scientific terms used herein have the same meaning as commonly understood by one of ordinary skill in the art to which this invention belongs. In case of conflict, the specification, including definitions, will control.

Although methods and materials similar or equivalent to those described herein can be used in the practice or testing of the invention, suitable methods and materials are described herein.

Unless stated otherwise, all percentages, parts, ratios, etc., are by weight.

When an amount, concentration, or other value or parameter is given as either a range, preferred range or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

When the term “about” is used in describing a value or an end-point of a range, the disclosure should be understood to include the specific value or end-point referred to.

As used herein, the terms “comprises,” “comprising,” “includes,” “including,” “containing,” “characterized by,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or.

The transitional phrase “consisting essentially of” limits the scope of a claim to the specified materials or steps and those that do not materially affect the basic and novel characteristic(s) of the claimed invention.

Where applicants have defined an invention or a portion thereof with an open-ended term such as “comprising,” it should be readily understood that (unless otherwise stated) the description should be interpreted to also describe such an invention using the term “consisting essentially of”.

Use of “a” or “an” are employed to describe elements and components of the invention. This is merely for convenience and to give a general sense of the invention. This description should be read to include one or at least one and the singular also includes the plural unless it is obvious that it is meant otherwise.

In describing certain polymers it should be understood that sometimes applicants are referring to the polymers by the monomers used to produce them or the amounts of the monomers used to produce the polymers. While such a description may not include the specific nomenclature used to describe the final polymer or may not contain product-by-process terminology, any such reference to monomers and amounts should be interpreted to mean that the polymer comprises those monomers or that amount of the monomers, and the corresponding polymers and compositions thereof.

In describing and/or claiming this invention, the term “copolymer” is used to refer to polymers containing two or more monomers.

The term “acid copolymer” as used herein refers to a polymer comprising copolymerized units of an α-olefin, an α,β-ethylenically unsaturated carboxylic acid, and optionally other suitable comonomer(s) such as an α,β-ethylenically unsaturated carboxylic acid ester.

The term “ionomer” as used herein refers to a polymer that comprises ionic groups that are carboxylates, for example alkali metal carboxylates, alkaline earth carboxylates, transition metal carboxylates and/or mixtures of such carboxylates. Such polymers are generally produced by partially or fully neutralizing the carboxylic acid groups of an acid copolymer, as defined herein, for example by reaction with a base. An example of a transition metal ionomer as used herein is a zinc ionomer, for example a copolymer of ethylene and methacrylic acid wherein all or a portion of the carboxylic acid groups of the copolymerized methacrylic acid units are in the form of zinc carboxylates.

The invention provides a colored multi-layer polymeric sheet that can be used to form an encapsulant layer of a solar cell module. By “multi-layer”, it is meant that the sheet comprises two or more polymeric sub-layers, i.e., two surface sub-layers (which form the two outermost surfaces of the multi-layer sheet) and optionally one or more inner sub-layers (which are positioned between the two surface sub-layers), wherein each of the sub-layers may comprise the same polymer or different polymers. By different polymers is meant that the polymers are chemically distinct. For example, they may comprise copolymerized units of different monomers within the main polymer chain. An example of two polymers having different copolymerized monomer units would be a copolymer of ethylene and methyl acrylate vs. a copolymer of ethylene and ethyl acrylate. Another example would be an ethylene homopolymer vs. a dipolymer of ethylene and a comonomer. Different polymers may also include polymers that are products prepared by two polymerization techniques that introduce different molecular architecture into the polymer chains. Examples include polymerizations that result in different monomer sequencing of the polymer chain, for example alternating vs. random copolymerization or graft polymerization vs. copolymerization.

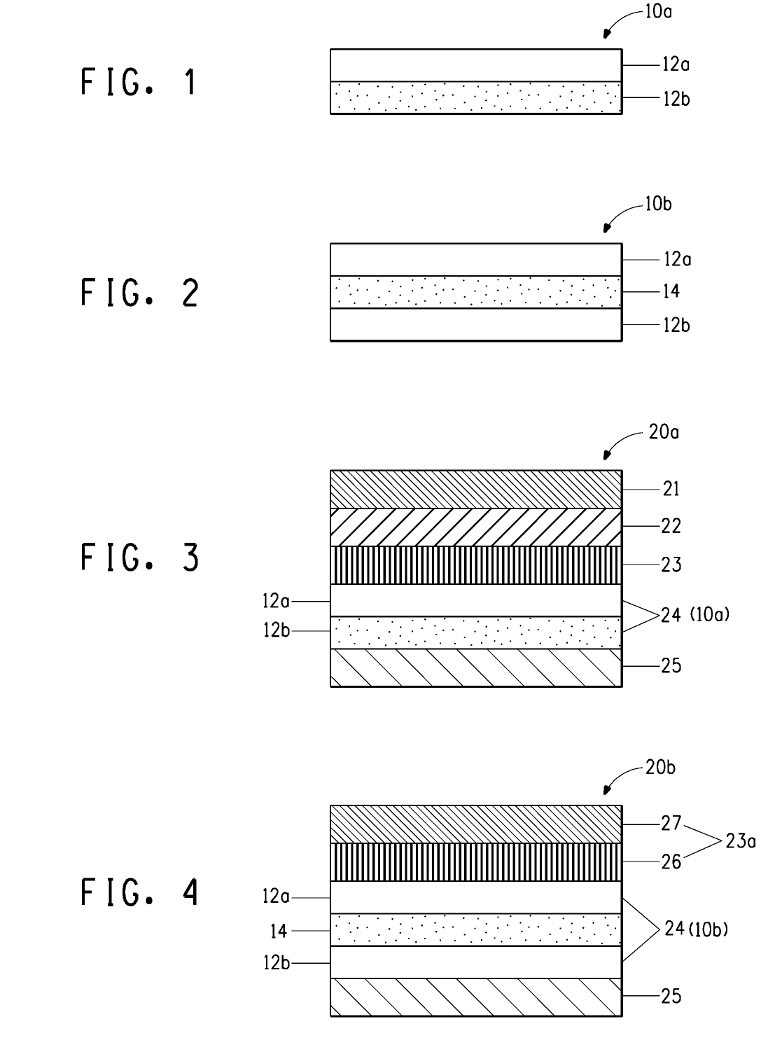

In the colored multi-layer polymeric sheet, one or more of the sub-layers are colored sub-layers while at least one of the two surface sub-layers is an uncolored sub-layer. A “colored sub-layer” refers to a polymeric sub-layer sheet comprising a suitable polymer and an electrically conductive color pigment (such as carbon black) and an “uncolored sub-layer” refers to a polymeric sub-layer sheet comprising a suitable polymer wherein the polymer is substantially free of any electrically conductive color pigment. By “substantially free of any electrically conductive color pigment”, it is meant that the composition comprises less than about 1 ppm, by weight of the total composition, of electrically conductive color pigment, based on the total weight of the composition. When the colored multi-layer polymeric sheet has three or more sub-layers, it is preferred that both the two surface sub-layers are uncolored and at least one of the inner sub-layer(s) is colored. More preferably, with reference to FIGS. 1 and 2 respectively, the colored multi-layer sheet (i) is in the form of a bi-layer sheet (10a) and comprises an uncolored first surface sub-layer (12a) and a colored second surface sub-layer (12b) or (ii) is in the form of a tri-layer sheet (10b) and comprises two uncolored surface sub-layers (12a and 12b) and one colored inner sub-layer (14).

In addition to the electrically conductive color pigments, the colored sub-layers may further comprise any other color pigment(s). Preferably, the pigments used in sub-layers of the colored multi-layer polymeric sheet have high fade resistance when exposed to sunlight (color fastness) and high thermal stability. More preferably, the pigments may be reduced to small particle sizes so that the haze level of the final laminate can be maintained at a low level.

Using Color Index nomenclature, the other color pigments that may be used in the colored multi-layer sheets include, but are not limited to,
PB60 (such as CROMOPHTAL Blue A3R from Ciba Specialty Chemicals Corporation, Tarrytown, N.Y. (Ciba)),
PR202 (such as CROMOPHTAL Magenta P from Ciba),
PR264 (such as IRGAZIN DPP Rubine TR from Ciba),
PY151 (such as VERSAL Yellow H4G from Synthesia, a. s., Czech Republic),
PB15.3 (such as PV Fast Blue BG from Clariant Corporation, Charlotte, N.C. (Clariant)),
PR122 (such as PV Fast Pink 122 from Clariant),
PV19 (such as PV Fast Red E3B from Clariant),
PY181 (such as PV Fast Yellow H3R from Clariant),
PR254 (such as VERSAL D3G from Clariant),
PV15.1 (such as HELIOGEN Blue K 6911D from BASF Corporation, Florham Park, N.J. (BASF)),
PG7 (such as PV Fast Green GNX from Clariant),
PB29 (such as Ultramarine Blue from Nubiola, Barcelona, Spain),
PB15.6 (such as HELIOGEN Blue L6700 F from BASF),
PY129 (such as IRGAZIN Yellow 5GLT and IRGAZIN Yellow 5GT from Ciba),
PY109 (such as IRGAZIN Yellow 2GLTE from Ciba),
PY42 (such as SICOTRANS Yellow L1915 from BASF),
PB7 (such as RAVEN 2500 Ultra Carbon Black from Columbian Chemicals Company, Marietta, Ga.),
PB15:4 (such as ENDUROPHTHAL Blue GF BT617D from Clariant),
DPP/QA (such as MONASTRAL Brilliant Red RT380D from Ciba),
PR209 (such as HOSTAPERM EG Trans from Clariant),
PR202 (such as SUNFAST Magenta 228-1215 from Sun Chemical Corporation, Parsippany, N.J. (Sun)),
PR149 (such as SUN 264-0414 Fast Red BL from Sun),
   and combinations of two or more thereof. Most preferably, the other color pigments are selected from PY42, PB7, PB15:4, DPP/QA, PR209, PR202, PR149, and combinations of two or more thereof.

Preferably, the color pigment(s) are present in each of the colored sub-layers at a level of about 50 to about 1000 ppm, or more preferably at a level of about 100 to about 500 ppm, based on the total weight of the composition of the sub-layer. Suitable colored sheet or film compositions and the processes to produce them are disclosed in European Patent No. EP1 194 289 B1.

Each of the sub-layers of the colored multi-layer sheet may comprise the same or different polymer resins that are independently selected from for example, ethylene vinyl acetate copolymers, poly(vinyl acetals) (including acoustic grade poly(vinyl acetals)), polyurethanes, poly(vinyl chlorides), polyethylenes (e.g., linear low density polyethylenes), polyolefin block elastomers, copolymers of an α-olefin and an α,β-ethylenically unsaturated carboxylic acid ester (e.g., ethylene methyl acrylate copolymer and ethylene butyl acrylate copolymer), acid copolymers as previously defined herein, ionomers as previously defined herein, silicone elastomers and epoxy resins. Preferably, each of the sub-layers of the multi-layer sheet comprises a common (i.e. identical) polymer component that is selected from poly(vinyl butyrals), acid copolymers, ionomers, poly(ethylene vinyl acetates), and polyurethanes.

The polymeric compositions of the sub-layers of the colored multi-layer sheet may further contain other additives known within the art. The additives may include, but are not limited to, processing aids, flow enhancing additives, lubricants, flame retardants, impact modifiers, nucleating agents, anti-blocking agents (such as silica), thermal stabilizers, UV absorbers, UV stabilizers, adhesives, dispersants, surfactants, chelating agents, coupling agents, reinforcement additives (such as glass fiber and fillers), and combinations of two or more thereof.

The polymeric compositions of the sub-layers may contain an effective amount of a thermal stabilizer. Thermal stabilizers are well-known in the art. Any known thermal stabilizer may find utility within the invention. Preferable general classes of thermal stabilizers include, but are not limited to, phenolic antioxidants, alkylated monophenols, alkylthiomethylphenols, hydroquinones, alkylated hydroquinones, tocopherols, hydroxylated thiodiphenyl ethers, alkylidenebisphenols, O-, N- and S-benzyl compounds, hydroxybenzylated malonates, aromatic hydroxybenzyl compounds, triazine compounds, aminic antioxidants, aryl amines, diaryl amines, polyaryl amines, acylaminophenols, oxamides, metal deactivators, phosphites, phosphonites, benzylphosphonates, ascorbic acid (vitamin C), compounds which destroy peroxide, hydroxylamines, nitrones, thiosynergists, benzofuranones, indolinones, and the like and mixtures thereof. More preferably, the thermal stabilizer is a member of the class of bis-phenolic antioxidants, especially when used in combination with a triethylene glycol di-2-ethylhexanoate plasticizer. Suitable specific bis-phenolic antioxidants include 2,2′-ethylidenebis(4,6-di-t-butylphenol); 4,4′-butylidenebis(2-t-butyl-5-methylphenol); 2,2′-isobutylidenebis(6-t-butyl-4-methylphenol); and 2,2′-methylenebis(6-t-butyl-4-methylphenol). Some commercially available bis-phenolic antioxidants include Anox® 29, Lowinox® 22M46, Lowinox® 44B25, and Lowinox® 22IB46 (Great Lakes, Indianapolis, Ind.). The polymeric sub-layer may contain up to about 10 wt %, preferably up to about 5 wt %, and more preferably up to about 1 wt % of thermal stabilizers, based on the total weight of the sub-layer composition. In certain embodiments, it is preferred that no thermal stabilizer is included in the sub-layer composition.

The polymeric compositions of the sub-layers may contain an effective amount of UV absorbers. UV absorbers are well-known in the art. Any known UV absorber may find utility within the invention. Preferable general classes of UV absorbers include, but are not limited to, benzotriazoles, hydroxybenzophenones, hydroxyphenyltriazines, esters of substituted and unsubstituted benzoic acids, and mixtures of two or more thereof. The polymeric sub-layers may contain up to about 10 wt %, preferably up to about 5 wt %, and more preferably up to about 1 wt % of UV absorbers, based on the total weight of the sub-layer composition. In certain embodiments, it is preferred that no UV absorber is included in the sub-layer composition.

The polymeric compositions of the sub-layers may incorporate an effective amount of hindered amine light stabilizers (HALS). Hindered amine light stabilizers are well-known in the art. Generally, hindered amine light stabilizers are disclosed to be secondary, tertiary, acetylated, N-hydrocarbyloxy substituted, hydroxy substituted N-hydrocarbyloxy substituted, or other substituted cyclic amines which are further characterized by a degree of steric hindrance, generally as a result of substitution of an aliphatic group or groups on the carbon atoms adjacent to the amine function. The polymeric sub-layers may contain up to about 10 wt %, preferably up to about 5 wt %, and more preferably up to about 1 wt % of the hindered amine light stabilizers, based on the total weight of the sub-layer composition. In certain embodiments, it is preferred that no hindered amine light stabilizer is included in the sub-layer composition.

The colored multi-layer sheet may have a total thickness of about 10 to about 250 mil (about 0.25 to about 6.35 mm), preferably about 15 to about 90 mil (about 0.38 to about 2.28 mm), more preferably about 15 to about 60 mil (about 0.38 to about 1.52 mm), yet more preferably about 15 to about 50 mil (about 0.38 to about 1.27 mm), yet more preferably about 15 to about 45 mil (about 0.38 to about 1.14 mm), yet more preferably about 15 to about 40 mil (about 0.38 to about 1.02 mm), yet more preferably about 20 to about 40 mil (0.51 to about 1.02 mm), and most preferably about 20 to about 35 mil (0.51 to about 0.89 mm). And each sub-layer of the colored multi-layer sheet may independently have a thickness of about 0.5 to about 200 mil (about 0.013 to about 5.1 mm), preferably about 3 to about 120 mil (about 0.076 to about 3 mm), more preferably about 3 to about 60 mil (about 0.076 to about 1.52 mm), and most preferably about 10 to about 30 mil (about 0.25 to about 0.76 mm).

The colored multi-layer sheets may have smooth or rough surfaces on one or both sides. Preferably, the colored multi-layer sheet has rough surfaces on both sides. Such a design will facilitate deaeration during the lamination process when the colored multi-layer sheet is included in a solar cell module as an encapsulant layer. Rough surfaces can be created by mechanical embossing or by melt fracture during extrusion of the sheets followed by quenching so that surface roughness is retained during handling. The surface pattern can be applied to the colored multi-layer encapsulant sheet through processes well known in the art. For example, the as-extruded sheet may be passed over a specially prepared surface of a die roll positioned in close proximity to the exit of the die which imparts the desired surface characteristics to one side of the molten polymer. Thus, when the surface of such roll has minute peaks and valleys, the polymer sheet cast thereon will have a rough surface on the side that contacts the roll. The surface will generally conform to the configuration of the valleys and peaks of the roll surface. Such die rolls are disclosed in, e.g., U.S. Pat. No. 4,035,549, U.S. Patent Publication No. 2003/0124296, and U.S. patent application Ser. No. 11/725,622, filed Mar. 20, 2007.

In one particular embodiment, each of the sub-layers of the colored multi-layer polymeric sheet comprises a poly(vinyl butyral), at least one of which layers is substantially free of color pigment(s).

Poly(vinyl butyral) is a vinyl resin resulting from the condensation of polyvinyl alcohol with butyraldehyde and may be produced by aqueous or solvent acetalization. For example, poly(vinyl butyral) resins can be produced as disclosed in U.S. Pat. Nos. 3,153,009 and 4,696,971.

A suitable poly(vinyl butyral) may have a weight average molecular weight ranging from about 30,000 to about 600,000, preferably from about 45,000 to about 300,000, or more preferably from about 200,000 to 300,000, as measured by size exclusion chromatography using low angle laser light scattering. The poly(vinyl butyral) may also contain, on a weight basis, about 12% to about 23%, preferably about 14% to about 21%, more preferably about 15% to about 19.5%, or most preferably about 15% to about 19%, of hydroxyl groups calculated as polyvinyl alcohol (PVOH). The hydroxyl number can be determined according to standard methods, such as ASTM D1396-92. In addition, the poly(vinyl butyral) may include up to about 10%, or preferably up to about 3% of residual ester groups, calculated as polyvinyl ester, typically acetate groups, with the balance being butyraldehyde acetal. The poly(vinyl butyral) may also contain a minor amount of acetal groups other than butyral, e.g., 2-ethyl hexanal, as disclosed in U.S. Pat. No. 5,137,954.

Typically, each of the poly(vinyl butyral) sub-layers of the colored multi-layer sheet also comprises a plasticizer and the amount depends on the specific poly(vinyl butyral) resin and the properties desired in the application. The plasticizer improves the flexibility and processability of the multi-layer sheets. Suitable plasticizers are known within the art, e.g., as disclosed in U.S. Pat. No. 3,841,890; 4,144,217; 4,276,351; 4,335,036; 4,902,464; 5,013,779 and PCT Patent Application No. WO 96/28504. Plasticizers commonly employed are esters of a polybasic acid or a polyhydric alcohol. Preferred plasticizers include, but are not limited to, diesters obtained by the reaction of triethylene glycol or tetraethylene glycol with aliphatic carboxylic acids having from 6 to 10 carbon atoms, diesters obtained from the reaction of sebacic acid with aliphatic alcohols having from 1 to 18 carbon atoms, oligoethylene glycol di-2-ethylhexanoate, tetraethylene glycol di-n-heptanoate, dihexyl adipate, dioctyl adipate, mixtures of heptyl and nonyl adipates, dibutyl sebacate, tributoxyethylphosphate, isodecylphenylphosphate, triisopropylphosphite, polymeric plasticizers (e.g., oil-modified sebacic acid alkyds), mixtures of phosphates and adipates, mixtures of adipates and alkyl benzyl phthalates, and mixtures of two or more of such plasticizers. More preferred plasticizers include triethylene glycol di-2-ethylhexanoate, tetraethylene glycol di-n-heptanoate, dibutyl sebacate, and mixtures of two or more thereof. A single plasticizer or a mixture of plasticizers can be present in the sheet composition. For convenience, when describing the sheet or film compositions of the invention, a mixture of plasticizers can also be referred to herein as “plasticizer”. That is, the singular form of the word “plasticizer” as used herein may represent the use of either one plasticizer or a mixture of two or more plasticizers.

Preferably, each of the poly(vinyl butyral) sub-layers incorporates about 15 to about 60 wt %, more preferably about 15 to about 50 wt %, or most preferably about 25 to about 40 wt % of a plasticizer based on the total weight of the sub-layer composition.

In one particular embodiment, each of the poly(vinyl butyral) sub-layers of the colored multi-layer sheet contains a single plasticizer in the amount of from about 28 to about 40 wt %, based on the weight of the sub-layer composition. Such acoustic poly(vinyl butyral) compositions are disclosed in PCT Publication No. WO 2004/039581.

An adhesion control additive may also be contained in the poly(vinyl butyral) sub-layer(s). The addition of such adhesion control additives can, for example, control the adhesive bond between the colored multi-layer sheet and the adjacent layers when used as an encapsulant layer in a solar cell module. These additives are generally alkali metal or alkaline earth metal salts of organic and inorganic acids. Preferably, they are alkali metal or alkaline earth metal salts of organic carboxylic acids having from 2 to 16 carbon atoms. More preferably, they are magnesium or potassium salts of organic carboxylic acids having from 1 to 16 carbon atoms. Specific examples of the adhesion control additives include potassium acetate, potassium formate, potassium propanoate, potassium butanoate, potassium pentanoate, potassium hexanoate, potassium 2-ethylbutylate, potassium heptanoate, potassium octanoate, potassium 2-ethylhexanoate, magnesium acetate, magnesium formate, magnesium propanoate, magnesium butanoate, magnesium pentanoate, magnesium hexanoate, magnesium 2-ethylbutyrate, magnesium heptanoate, magnesium octanoate, magnesium 2-ethylhexanoate and the like and mixtures thereof. The adhesion control additive is typically used in the range of about 0.001 to about 0.5 wt % based on the total weight of the sub-layer composition.

Surface tension controlling agents, such as Trans® 290 or 296 (available from the Trans-Chemco Inc., Bristol, Wis.) or Q-23183® (available from the Dow Chemical Company, Midland, Mich.) may also be contained in the poly(vinyl butyral) sub-layers.

The colored multi-layer sheet can be produced by any suitable process. For example, a pre-formed colored multi-layer sheet may be produced by first separately preparing each of the component sub-layer sheets through any suitable process and then laminating or bonding the sub-layers to form the multi-layer sheet. In a preferred embodiment where the multi-layer sheet is not pre-formed, the separately prepared sub-layer sheets may be stacked in the appropriate order but not laminated or bonded together until after the sub-layer sheets have been placed in a solar cell pre-lamination assembly. Lamination of the sub-layers takes place during the usual lamination process used in preparing the solar cell modules, e.g. the process used to bond for example all the component layers of the solar cell module. Each of the sub-layer sheets of the colored multi-layer sheet may be independently prepared through dipcoating, solution casting, compression molding, injection molding, lamination, melt extrusion, melt coextrusion, blown film, extrusion coating, tandem extrusion coating, or any other procedures that are known to those of skill in the art. It is preferred that each of the sub-layers has at least one rough surface to facilitate deaeration during the lamination step. It is also to be understood that such rough surface is only temporary and will be melted to form a smooth surface due to the elevated temperature and pressure associated with autoclaving and other lamination processes.

In certain embodiments, the colored multi-layer sheets may also be produced directly by a co-extrusion process, without first separately preparing each of the component sub-layers.

An exemplary process for the production of a colored or uncolored poly(vinyl butyral) sub-layer sheet is described herein with the understanding that such a process may be easily modified by one skilled in the art. The plasticized poly(vinyl butyral) sub-layer sheets may be formed by initially mixing the poly(vinyl butyral) resin with plasticizer and then extruding the formulation through a sheet-shaping die, i.e. forcing molten, plasticized poly(vinyl butyral) through a horizontally long, vertically narrow die opening substantially conforming in length and width to that of the sheet being formed. The plasticized poly(vinyl butyral) compositions can generally be extruded at a temperature of about 225° C. to about 245° C. Rough surfaces on one or both sides of the extruded sheet are preferably provided by the design of the die opening and the temperature of the die exit surfaces through which the extrudate passes, as disclosed in, e.g., U.S. Pat. No. 4,281,980. Alternative techniques for producing a preferable rough surface on an extruded poly(vinyl butyral) sheet involve the specification and control of one or more of polymer molecular weight distribution, water content and melt temperature. Various processes for producing poly(vinyl butyral) sheets are disclosed in U.S. Pat. Nos. 2,904,844; 2,909,810; 3,679,788; 3,994,654; 4,161,565; 4,230,771; 4,292,372; 4,297,262; 4,575,540; 5,151,234; 5,886,675 and European Patent No. EP 0 185 863. In forming the colored poly(vinyl butyral) sub-layers, the color pigments may be incorporated into sheet compositions as disclosed in European Patent No. EP 1 194 289 B1. By use of such a process, little or no pigment agglomerates will be found in the laminates and, when present, agglomerates will be extremely small. This provides the laminates with a high percent clarity.

The invention further provides a solar cell module comprising at least one layer of the above described colored multi-layer polymeric sheets and a solar cell layer comprised of one or a plurality of solar cells and having a light-receiving side and a non-light-receiving side, wherein the colored multi-layer polymeric sheet is laminated to one side of the solar cell layer and serves as an encapsulant layer, and wherein the colored multi-layer polymeric sheet always has the at least one surface sub-layer that is not colored and is substantially free of any electrically conductive color pigment in direct contact with the solar cell layer. For the purpose of consistency, when the colored multi-layer polymeric sheet is referred to as an encapsulant layer in a solar cell module, the at least one uncolored surface sub-layer that is in direct contact with the solar cell layer will be referred to as the (uncolored) first surface sub-layer while the other surface sub-layer will be referred to as the (colored) second surface sub-layer, which may be either colored or uncolored. Preferably, the solar cells are electrically interconnected and/or arranged in a flat plane. It is also preferred that the colored multi-layer polymeric sheet is laminated to a non-light-receiving side of the solar cell layer and serves as a back encapsulant layer.

The term “solar cell” is meant to include any article which can convert light into electrical energy. Solar cells useful in the invention include, but are not limited to, wafer-based solar cells (e.g., c-Si or mc-Si based solar cells, as described above in the background section) and thin film solar cells (e.g., a-Si, μc-Si, CdTe, or Cl(G)S based solar cells, as described above in the background section). Within the solar cell layer, it is preferred that the solar cells are electrically interconnected. In addition, the solar cell layer may further comprise electrical wirings, such as cross ribbons and bus bars.

The solar cell module may further comprise additional encapsulant layers comprising any other suitable polymeric materials. Some specific examples of such polymeric materials include acid copolymers, ionomers, poly(ethylene vinyl acetates), poly(vinyl acetals) (including acoustic grade poly(vinyl acetals)), polyurethanes, poly(vinyl chlorides), polyethylenes (e.g., linear low density polyethylenes), polyolefin block elastomers, copolymers of an α-olefin and an α,β-ethylenically unsaturated carboxylic acid ester (e.g., ethylene methyl acrylate copolymer and ethylene butyl acrylate copolymer), silicone elastomers, epoxy resins, and combinations of two or more thereof. The particular choice of polymeric material will depend on the conditions to which the solar cell is exposed and is within the skill of those in the art.

The thickness of the individual optional additional encapsulant layers that are present in combination with the colored multi-layer sheet may independently range from about 1 to about 120 mils (0.026-3 mm), or preferably from about 1 to about 40 mils (0.026-1.02 mm), or more preferably from about 1 to about 20 mils (0.026-0.51 mm). All the encapsulant layer(s) comprised in the solar cell module may have smooth or rough surfaces. Preferably, the encapsulant layer(s) have rough surfaces to facilitate the deaeration of the laminates during the lamination process.

The solar cell module may yet further comprise an incident layer and/or a backing layer serving as the outermost layer(s) of the module at the light-receiving side and the non-light-receiving side, respectively.

The outermost layers of the solar cell modules, i.e., the incident layer and the backing layer, may be formed of any suitable sheets or films. Suitable sheets may be glass or plastic sheets, such as polycarbonates, acrylic polymers (i.e., thermoplastic polymers or copolymers of acrylic acid, methacrylic acid, esters of these acids, or acrylonitrile), polyacrylates, cyclic polyolefins (e.g., ethylene norbornene polymers), polystyrenes (preferably metallocene-catalyzed polystyrenes), polyamides, polyesters, fluoropolymers, or combinations of two or more thereof. In addition, metal sheets, such as aluminum, steel, galvanized steel, or ceramic plates may be utilized in forming the backing layer.

The term “glass” includes not only window glass, plate glass, silicate glass, sheet glass, low iron glass, tempered glass, tempered CeO-free glass, and float glass, but also colored glass, specialty glass (such as those types of glass containing ingredients to control solar heating), coated glass (such as those sputtered with metals (e.g., silver or indium tin oxide) for solar control purposes), E-glass, Toroglass, Solex® glass (PPG Industries, Pittsburgh, Pa.) and Starphire® glass (PPG Industries). Such specialty glasses are disclosed in, e.g., U.S. Pat. Nos. 4,615,989; 5,173,212; 5,264,286; 6,150,028; 6,340,646; 6,461,736; and 6,468,934. It is understood, however, that the type of glass to be selected for a particular module depends on the intended use.

Suitable film layers may be polymers that include but are not limited to, polyesters (e.g., poly(ethylene terephthalate) and poly(ethylene naphthalate)), polycarbonate, polyolefins (e.g., polypropylene, polyethylene, and cyclic polyolefins), norbornene polymers, polystyrene (e.g., syndiotactic polystyrene), styrene-acrylate copolymers, acrylonitrile-styrene copolymers, polysulfones (e.g., polyethersulfone, polysulfone, etc.), nylons, poly(urethanes), acrylic polymers, cellulose acetates (e.g., cellulose acetate, cellulose triacetates, etc.), cellophane, poly(vinyl chlorides) (e.g., poly(vinylidene chloride)), fluoropolymers (e.g., polyvinyl fluoride, polyvinylidene fluoride, polytetrafluoroethylene, ethylene-tetrafluoroethylene copolymers, etc.) and combinations of two or more thereof. The polymeric film may be bi-axially oriented polyester film (preferably poly(ethylene terephthalate) film) or a fluoropolymer film (e.g., Tedlar®, Tefzel®, and Teflon® films, from E. I. du Pont de Nemours and Company, Wilmington, Del. (DuPont)). Fluoropolymer-polyester-fluoropolymer (e.g., “TPT”) films are also preferred for some applications. Metal films, such as aluminum foil, may also be used as the backing layer.

The solar cell module may further comprise other functional film or sheet layers (e.g., dielectric layers or barrier layers) embedded within the module. Such functional layers may comprise any of the above mentioned polymeric films or those that are coated with additional functional coatings. For example, poly(ethylene terephthalate) films coated with a metal oxide coating, such as those disclosed within U.S. Pat. Nos. 6,521,825 and 6,818,819 and European Patent No. EP1182710, may function as oxygen and moisture barrier layers in the laminates.

If desired, a layer of nonwoven glass fiber (scrim) may also be included between the solar cell layers and the encapsulant layers to facilitate deaeration during the lamination process or to serve as reinforcement for the encapsulants. The use of such scrim layers is disclosed in, e.g., U.S. Pat. Nos. 5,583,057; 6,075,202; 6,204,443; 6,320,115; and 6,323,416 and European Patent No. EP0769818.

If desired, one or both surfaces of the incident layer films and sheets, the backing layer films and sheets, the encapsulant layers and other layers incorporated within the solar cell module may be treated prior to the lamination process to enhance the adhesion to other laminate layers. This adhesion enhancing treatment may take any form known within the art and may include flame treatments (see, e.g., U.S. Pat. Nos. 2,632,921; 2,648,097; 2,683,894; and 2,704,382), plasma treatments (see e.g., U.S. Pat. No. 4,732,814), electron beam treatments, oxidation treatments, corona discharge treatments, chemical treatments, chromic acid treatments, hot air treatments, ozone treatments, ultraviolet light treatments, sand blast treatments, solvent treatments, and combinations of two or more thereof. Also, the adhesion strength may be further improved by further applying an adhesive or primer coating on the surface of the laminate layer(s). For example, U.S. Pat. No. 4,865,711 discloses a film or sheet with improved bondability, which has a thin layer of carbon deposited on one or both surfaces. Other exemplary adhesives or primers may include silanes, poly(allyl amine) based primers (see e.g., U.S. Pat. Nos. 5,411,845; 5,770,312; 5,690,994; and 5,698,329), and acrylic based primers (see e.g., U.S. Pat. No. 5,415,942). The adhesive or primer coating may take the form of a monolayer of the adhesive or primer and have a thickness of about 0.0004 to about 1 mil (about 0.00001 to about 0.03 mm), or preferably, about 0.004 to about 0.5 mil (about 0.0001 to about 0.013 mm), or more preferably, about 0.004 to about 0.1 mil (about 0.0001 to about 0.003 mm).

Referring to FIG. 3, in one particular embodiment wherein the solar cells are formed of wafer-based self supporting solar cell units, the solar cell module (20a) may comprise, in order of position from the light source and thus from the front light-receiving side to the back non-light-receiving side, (a) an incident layer (21), (b) a front encapsulant layer (22), (c) a solar cell layer (23) comprising one or more electrically interconnected solar cells, (d) a back encapsulant layer (24), and (e) a backing layer (25), wherein the back encapsulant layer (24) comprises a colored multi-layer polymeric sheet (10a) as shown in FIG. 1.

Preferably, however, the solar cell modules (20b in FIG. 4) employ thin film solar cells and comprise, in order of position from the front light-receiving side to the back non-light-receiving side, (a) a solar cell layer (23a) comprising a superstrate (27) and a layer of thin film solar cell(s) (26) deposited thereon at the non-light-receiving side, (b) a (back) encapsulant layer (24), and (c) a backing layer (25), wherein the (back) encapsulant layer (24) comprises a colored multi-layer polymeric sheet (10b) as shown in FIG. 2.

Moreover, a series of the solar cell modules described above may be further linked to form a solar cell array, which can produce a desired voltage and current.

Exemplary solar cell modules may have the following laminate structures, in order of position from the top light-receiving side to the back non-light-receiving side, where CMS is an abbreviation for a colored multi-layer polymeric sheet disclosed herein:
thin film solar cells deposited on a supporting glass/CMS/glass;
thin film solar cells deposited on a supporting glass/CMS/glass;
thin film solar cells deposited on a supporting glass/CMS/glass;
glass/encapsulant sheet/solar cell/CMS/glass;
glass/encapsulant sheet/solar cell/CMS/glass;
glass/encapsulant sheet/solar cell/CMS/glass;
glass/CMS/solar cell/other encapsulant sheet/glass;
glass/CMS/solar cell/CMS/glass;
glass/encapsulant sheet/solar cell/CMS/fluoropolymer film (e.g., Tedlar® film); and
fluoropolymer film/encapsulant sheet/solar cell/CMS/fluoropolymer film,
   wherein the colored multi-layer sheet (CMS) is always positioned in a way that the uncolored first surface sub-layer is in direct contact with the solar cells. In addition, besides the Tedlar® film from DuPont, suitable fluoropolymer films also include TPT tri-layer films.

Any lamination process known in the art (including autoclave and non-autoclave processes) may be used to prepare the solar cell modules.

In an exemplary process, the component layers of the solar cell module are stacked in a desired order to form a pre-lamination assembly. The assembly is then placed into a bag capable of sustaining a vacuum (“a vacuum bag”), the air is drawn out of the bag by a vacuum line or other means, the bag is sealed while the vacuum is maintained (e.g., at least about 27-28 in Hg (689-711 mm Hg)), and the sealed bag is placed in an autoclave at a pressure of about 150 to about 250 psi (about 11.3 to about 18.8 bar), a temperature of about 130° C. to about 180° C., or about 120° C. to about 160° C., or about 135° C. to about 160° C., or about 145° C. to about 155° C., for about 10 to about 50 min, or about 20 to about 45 min, or about 20 to about 40 min, or about 25 to about 35 min. A vacuum ring may be substituted for the vacuum bag. One type of suitable vacuum bag is disclosed within U.S. Pat. No. 3,311,517. Following the heat and pressure cycle, the air in the autoclave is cooled without introducing additional gas to maintain pressure in the autoclave. After about 20 min of cooling, the excess air pressure is vented and the laminates are removed from the autoclave.

Alternatively, the pre-lamination assembly may be heated in an oven at about 80° C. to about 120° C., or about 90° C. to about 100° C., for about 20 to about 40 min, afterwhich the heated assembly is passed through a set of nip rolls so that the air in the void spaces between the individual layers may be squeezed out, and the edge of the assembly sealed. The assembly at this stage is referred to as a pre-press.

The pre-press may then be placed in an air autoclave where the temperature is raised to about 120° C. to about 160° C., or about 135° C. to about 160° C., at a pressure of about 100 to about 300 psi (about 6.9 to about 20.7 bar), or preferably about 200 psi (13.8 bar). These conditions are maintained for about 15 to about 60 min, or about 20 to about 50 min, afterwhich the air is cooled while no more air is introduced to the autoclave. After about 20 to about 40 min of cooling, the excess air pressure is vented and the laminated products are removed from the autoclave.

The solar cell modules may also be produced through non-autoclave processes. Such non-autoclave processes are disclosed, e.g., in U.S. Pat. Nos. 3,234,062; 3,852,136; 4,341,576; 4,385,951; 4,398,979; 5,536,347; 5,853,516; 6,342,116; and 5,415,909, U.S. Patent Publication No. 20040182493, European Patent No. EP1235683 B1, and PCT Patent Publication Nos. WO9101880 and WO03057478. Generally, the non-autoclave processes include heating the pre-lamination assembly and the application of vacuum, pressure or both. For example, the assembly may be successively passed through heating ovens and nip rolls.

These examples of lamination processes are not intended to be limiting. Essentially any lamination process may be used.

If desired, the edges of the solar cell module may be sealed by any means disclosed in the art to reduce moisture and air intrusion. Moisture and air are recognized in the art to have potential degradative effects on the efficiency and lifetime of the solar cell(s). Suitable materials useful in sealing the solar cell module edges include, but are not limited to, butyl rubber, polysulfide, silicone, polyurethane, polypropylene elastomers, polystyrene elastomers, block elastomers, styrene-ethylene-butylene-styrene (SEBS), and the like.

The invention is further illustrated in the following examples of certain embodiments.

### EXAMPLES

The following Examples are intended to be illustrative of the invention, and are not intended in any way to limit the scope of the invention.

### Lamination Process 1:

The component layers of the laminate are stacked to form a pre-lamination assembly. For a laminate containing a film layer as the incident or backing layer, a cover glass sheet is placed over the film layer. The pre-lamination assembly is then placed within a vacuum bag, the vacuum bag is sealed and a vacuum is applied to remove the air from the vacuum bag. The bag is placed into an oven and while maintaining the application of the vacuum to the vacuum bag, the vacuum bag is heated at 135° C. for 30 minutes. The vacuum bag is then removed from the oven and allowed to cool to room temperature (25±5° C.). The resulting laminate is removed from the vacuum bag after the vacuum is released.

### Lamination Process 2:

The component layers of the laminate are stacked to form a pre-lamination assembly. For an assembly containing a polymeric film layer as the outer surface layer, a cover glass sheet is placed over the film layer. The pre-lamination assembly is then placed within a vacuum bag, which is sealed and a vacuum is applied to remove the air from the vacuum bag. The bag is placed into an oven and heated to about 90° C. to about 100° C. for 30 minutes to remove any air contained between the assembly. The assembly is then subjected to autoclaving at 140° C. for 30 minutes in an air autoclave to a pressure of 200 psig (14.3 bar). The air is cooled and no further air is introduced to the autoclave. After 20 minutes of cooling and when the air temperature reaches less than about 50° C., the excess pressure is vented and the vacuum bag containing the laminated assembly is removed from the autoclave. The resulting laminate is then removed from the vacuum bag.

### Comparative Example CE 1 and Example E1

CE1 was a bi-layer sheet made of two 15 mil (0.38 mm) thick gray-colored poly(vinyl butyral) sheets and E1 was a bi-layer sheet made of one 15 mil thick uncolored poly(vinyl butyral) sheet and one 15 mil thick gray-colored poly(vinyl butyral) sheet.

The gray-colored poly(vinyl butyral) sheet was prepared from PVB 1, a composition comprising 73.3 parts per hundred (pph) of a poly(vinyl butyral) polymer resin, 26.7 pph of triethylene glycol di-2-ethylhexanoate, and 200 ppm of a pigment mixture, based on the total weight of the composition, wherein the poly(vinyl butyral) polymer resin has a hydroxyl group content of 18.8% hydroxyl groups calculated as polyvinyl alcohol (PVOH hydroxyl), and wherein the pigment mixture was made of, based on the total weight of the pigment mixture, 25 wt % carbon black, 25 wt % PB15:4 blue pigment and 50 wt % PR 209 red pigment.

The uncolored poly(vinyl butyral) sheet was prepared from PVB 2, a composition comprising 73.3 pph of a poly(vinyl butyral) polymer resin and 26.7 pph of triethylene glycol di-2-ethylhexanoate, based on the total weight of the composition, wherein the poly(vinyl butyral) polymer resin has a hydroxyl group content of 18.8% calculated as polyvinyl alcohol (PVOH hydroxyl).

In preparing each of the bi-layer sheets, the two component sub-layer sheets were placed adjacent to and in contact with each other and between two 2 mil (0.051 mm) thick poly(ethylene terephthalate) (PET) films, and this structure was placed between two lites of glass to form a “glass/PET/(bi-layer PVB)/PET/glass” structure. Such a structure was subject to autoclave, after which the two PET films and the two lites of glass were removed. The bi-layer sheets were further conditioned at various relative humidity conditions (RH) for a minimum of 16 hours prior to subjecting to a volume resistivity measurement in accordance with ASTM D257 using a Hiresta-UP from Mitsubishi Chemical Corporation, Japan. The various RH used in conditioning the bi-sheets and the volume resistivity results are reported below in Table 1.

TABLE 1

| | Average Volume Resistivity | | |
|---|---|---|---|
| Sample No. | 10% RH | 28% RH | 75% RH |
| CE1 | 4.08E+11 | 1.88E+11 | 2.56E+10 |
| E1 | 5.37E+11 | 2.89E+11 | 4.53E+10 |

### Examples E2-15

A series of 12×12 in (305×305 mm) solar cell modules having the laminate structures described in Table 2 are assembled and laminated by either Lamination Process 1 (E2-E8) or Lamination Process 2 (E9-E15). Layers 1 and 2 constitute the incident layer and the front-sheet encapsulant layer, respectively, and Layers 4 and 5 constitute the back-sheet encapsulant layer and the backing layer, respectively, where applicable. In addition, in each laminate structure, the uncolored surface sub-layer of each of the colored multi-layer sheets (CMS 1-4) is in direct contact with the solar cell layer.

TABLE 2
Solar Cell Laminate Structure

| Sample # | Layer 1 | Layer 2 | Layer 3 | Layer 4 | Layer 5 |
|---|---|---|---|---|---|
| E2, E9 | | | ⁹Solar Cell 1 | ³CMS 3 | ⁸Glass 2 |
| E3, E10 | | | ⁹Solar Cell 1 | ¹CMS 1 | ⁸Glass 2 |
| E4, E11 | | | ¹⁰Solar Cell 2 | ⁴CMS 4 | ⁸Glass 2 |
| E5, E12 | | | ¹⁰Solar Cell 2 | ²CMS 2 | ⁸Glass 2 |
| E6, E13 | | | ¹¹Solar Cell 3 | ¹CMS 1 | ⁸Glass 2 |
| E7, E14 | ⁷Glass 1 | ⁶PVB A | ¹²Solar Cell 4 | ²CMS 2 | ⁸Glass 2 |
| E8, E15 | ⁸Glass 2 | ⁵PVB 3 | ¹²Solar Cell 4 | ¹CMS 1 | ⁸Glass 2 |

¹CMS 1 - a tri-layer sheet having (a) two surface sub-layers, each of which comprises an uncolored composition that is substantially the same as PVB 2 (as used in E1) and having a thickness of 10 mil (0.25 mm) and (b) an inner sub-layer comprising a gray-colored composition that is substantially the same as PVB 1 (as used in CE1 and E1) and having a thickness of 5 mil (0.13 mm).
²CMS 2 - a bi-layer sheet having (a) a 10 mil (0.25 mm) thick first sub-layer comprising an uncolored composition that is substantially the same as PVB 2 and (b) a 10 mil (0.25 mm) thick second sub-layer comprising a gray-colored composition that is substantially the same as PVB 1.
³CMS 3 - a bi-layer sheet having (a) a 15 mil (0.38 mm) thick first sub-layer comprising an uncolored composition that is substantially the same as PVB 2 and (b) a 15 mil (0.38 mm) thick second sub-layer comprising a gray-colored composition that is substantially the same as PVB 1.
⁴CMS 4 - a tri-layer sheet having (a) two surface sub-layers, each of which comprises an uncolored composition that is substantially the same as PVB 2 and having a thickness of 15 mil (0.38 mm) and (b) a 15 mil (0.38 mm) thick inner sub-layer comprising a gray-colored composition that is substantially the same as PVB 1.
⁵PVB 3 - a 20 mil (0.51 mm) thick BUTACITE ® B51V poly(vinyl butyral) sheet obtained from DuPont.
⁶PVB A - a 30 mil thick sheet formed of a composition comprising 100 parts per hundred (pph) poly(vinyl butyral) with a hydroxyl number of 15 and 48.5 pph tetraethylene glycol diheptanoate and prepared substantially as disclosed in PCT Patent Publication No. WO 2004/039581.
⁷Glass 1 - Starphire ® glass from the PPG Corporation.
⁸Glass 2 - a clear annealed float glass plate having a thickness of 2.5 mm.
⁹Solar Cell 1 - a 12 × 12 in (305 × 305 mm) a-Si thin film photovoltaic device supported on a glass substrate (as disclosed in U.S. Pat. No. 5,507,881 and U.S. Pat. Publication No. 2007/0209699).
¹⁰Solar Cell 2 - a 12 × 12 in (305 × 305 mm) CIGS thin film photovoltaic device supported on a glass substrate (as disclosed in U.S. Pat. Nos. 6,040,521 and 6,258,620).
¹¹Solar Cell 3 - a 10 × 10 in (254 × 254 mm) CIS based thin film solar cell (as disclosed in U.S. Pat. No. 6,353,042, column 6, line 19).
¹²Solar Cell 4 - a silicon solar cell made from a 10 × 10 in (254 × 254 mm) polycrystalline EFG-grown wafer (as disclosed in U.S. Pat. No. 6,660,930, column 7, line 61).

What is claimed is:

1. A solar cell module comprising a laminate structure, the laminate structure comprising a solar cell layer and a colored multi-layer polymeric sheet, wherein
(A) the solar cell layer is selected from the group consisting of solar cell layers comprising a single solar cell and solar cell layers comprising a plurality of electrically interconnected solar cells;
(B) the solar cell layer has a light-receiving side and a non-light-receiving side; and
(C) the colored multi-layer polymeric sheet comprises a first surface sub-layer that is positioned such that it is adjacent to and in direct contact with the solar cell layer, a second surface sub-layer positioned such that it does not contact the solar cell layer, and optionally at least one inner sub-layer positioned between the two surface sub-layers, wherein
(i) the first surface sub-layer is uncolored and substantially free of electrically conductive color pigment; and
(ii) at least one sub-layer, other than the first surface sub-layer, is colored and comprises at least one electrically conductive color pigment.

2. A module of claim 1, wherein the colored multi-layer polymeric sheet is in the form of a bi-layer sheet and the second surface sub-layer is colored and comprises the at least one electrically conductive color pigment.

3. A module of claim 1, wherein the colored multi-layer polymeric sheet is in the form of a tri-layer sheet having a first surface sub-layer, a second surface sub-layer and an inner sub-layer, wherein the inner sub-layer is colored, and the second surface sub-layer is uncolored and substantially free of any electrically conductive color pigment.

4. A module of claim 1, wherein the electrically conductive color pigment is selected from the group consisting of carbon blacks and is present in the colored sub-layer at a level of about 50 to about 100 ppm by weight, based on the total weight of the sub-layer.

5. A module of claim 1, wherein each of the sub-layers independently comprises a polymer selected from the group consisting of ethylene vinyl acetate copolymers, poly(vinyl acetals), polyurethanes, polyvinylchlorides, polyethylenes, polyolefin block elastomers, copolymers of an α-olefin and an α,β-ethylenically unsaturated carboxylic acid ester, copolymers of an α-olefin and an α,β-ethylenically unsaturated carboxylic acid, ionomers of copolymers of an α-olefin and an α,β-ethylenically unsaturated carboxylic acid, silicone elastomers, epoxy resins, and mixtures thereof.

6. A module of claim 1, wherein each of the sub-layers of the colored multi-layer polymeric sheet comprises a poly(vinyl butyral) and a plasticizer.

7. A module of claim 1, wherein the colored multi-layer polymeric sheet has a total thickness of about 15 to about 90 mil (0.38-2.28 mm) and each of the sub-layers has a thickness of about 3 to about 60 mil (0.076-1.52 mm).

8. A module of claim 1, wherein the colored multi-layer polymeric sheet is positioned in contact with the non-light-receiving side of the solar cell layer and is a back encapsulant layer.

9. A module of claim 8, further comprising a front encapsulant layer that is laminated to the light-receiving side of the solar cell layer and that comprises a polymer selected from the group consisting of acid copolymers, ionomers, ethylene vinyl acetate copolymers, poly(vinyl acetals), polyurethanes, polyvinylchlorides, polyethylenes, polyolefin block elastomers, copolymers of an α-olefin and an α,β-ethylenically unsaturated carboxylic acid ester, silicone elastomers, epoxy resins, and mixtures thereof.

10. A module of claim 1, further comprising an incident layer, wherein the incident layer is an outermost surface layer of the module and is positioned on the light-receiving side of the solar cell layer.

11. A module of claim 1, further comprising a backing layer, wherein the backing layer is an outermost surface layer of the module and is positioned on the non-light receiving side of the solar cell layer.

12. A module of claim 1, wherein the solar cells are wafer-based solar cells selected from the group consisting of crystalline silicon (c-Si) and multi-crystalline silicone (mc-Si) based solar cells.

13. A module of claim 12, which consists essentially of, in order of position from the front light-receiving side of the solar cell module, (i) an incident layer, (ii) a front encapsulant layer laminated to the light-receiving side of the solar cell layer, (iii) the solar cell layer, (iv) a back encapsulant layer laminated to the non-light receiving side of the solar cell layer, and (v) a backing layer, wherein the back encapsulant layer is the colored multi-layer sheet recited in claim 1.

14. A module of claim 1, wherein the solar cells are thin film solar cells selected from the group consisting of amorphous silicon (a-Si), microcrystalline silicon (μc-Si), cadmium telluride (CdTe), copper indium selenide (CIS), copper indium/gallium diselenide (CIGS), light absorbing dyes, and organic semiconductors based solar cells.

15. A module of claim 14, which consists essentially of, in order of position from the light-receiving side of the solar cell module (i) the solar cell layer, (ii) a back encapsulant layer comprising the colored multi-layer sheet recited in claim 1, and (iii) a backing layer, wherein the solar cell layer further comprises a superstrate upon which the thin film solar cells are deposited and the superstrate is positioned such that the superstrate is an outermost surface of the module on the light-receiving side of the solar cell layer.

16. A process for preparing a solar cell module, comprising: (i) providing an assembly comprising all the component layers recited in claim 1 and (ii) laminating the assembly to form the solar cell module.

17. A process of claim 16, wherein the assembly comprises all the component layers recited in claim 13.

18. A process of claim 16, wherein the assembly comprises all the component layers recited in claim 15.

19. A process of claim 16, wherein the laminating step is conducted by subjecting the assembly to heat.

20. A process of claim 19, wherein the laminating step further comprises subjecting the assembly to vacuum or pressure.

21. A process for preparing a solar cell module, comprising:
(A) providing an assembly comprising, in order of position,
(1) a solar cell layer,
(2) a first polymeric sheet that is uncolored and substantially free of any electrically conductive color pigment, and
(3) a second polymeric sheet that is colored and comprising at least one electrically conductive color pigment,
wherein
(i) the solar cell layer is selected from the group consisting of solar cell layers comprising a single solar cell and solar cell layers comprising a plurality of electrically interconnected solar cells;
(ii) the solar cell layer has a light-receiving side and a non-light-receiving side; and
(iii) the uncolored first polymeric sheet is in direct contact with the non-light-receiving side of the solar cell layer, and
(B) laminating the assembly to form the solar cell module.
